(19) United States
(12) Patent Application Publication
(10) Pub. No.: US 2016/0307700 A1
(43) Pub. Date: Oct. 20, 2016

(54) CAPACITOR COMPONENT AND BOARD HAVING THE SAME

(71) Applicant: SAMSUNG ELECTRO-MECHANICS CO., LTD., Suwon-si (KR)

(72) Inventor: Heung Kil PARK, Suwon-si (KR)

(21) Appl. No.: 15/096,571

(22) Filed: Apr. 12, 2016

(30) Foreign Application Priority Data
Apr. 20, 2015 (KR) 10-2015-0055398

(51) Int. Cl. H01G 2/06; H05K 1/18; H01G 4/012; H01G 4/248; H01G 4/30; H01G 4/12

(52) U.S. Cl. CPC H01G 2/065; H01G 4/30; H01G 4/12; H01G 4/012; H01G 4/248; H05K 1/181; H05K 2201/10015

(57) ABSTRACT

A capacitor component includes a capacitor including a plurality of internal electrodes, a capacitor body containing a piezoelectric material formed in a region between adjacent electrodes among the plurality of internal electrodes, and external electrodes connected to the plurality of internal electrodes; and support parts formed of a metal and disposed to be coupled to the capacitor and having an annular shape to alleviate vibrations generated by the capacitor.

### CROSS-REFERENCE TO RELATED APPLICATION

This application claims the benefit of priority to Korean Patent Application No. 10-2015-0055398, filed on Apr. 20, 2015 with the Korean Intellectual Property Office, the entirety of which is incorporated herein by reference.

### TECHNICAL FIELD

The present disclosure relates to a capacitor component and a board having the same.

### BACKGROUND

Electronic components using a ceramic material include capacitors, inductors, piezoelectric elements, varistors, and thermistors.

Among ceramic electronic components, multilayer ceramic capacitors (MLCCs), which have advantages such as compactness, guaranteed high capacitance, and ease of mountability, may be used in a wide range of electronic devices.

For example, MLCCs may be used as chip-type condensers installed on the printed circuit boards (PCBs) of various electronic products such as imaging devices (or video display apparatuses) including liquid crystal displays (LCDs), plasma display panels (PDPs), and the like, as well as computers, personal digital assistants (PDAs), cellular phones, and the like, to charge or discharge electricity.

An MLCC may have a structure in which a plurality of dielectric layers and internal electrodes, the internal electrodes having opposing polarities, are alternately disposed between the dielectric layers.

Here, the dielectric layers have piezoelectric properties, and thus, when a direct current (DC) or alternating current (AC) voltage is applied to an MLCC, a piezoelectric phenomenon may occur between internal electrodes, expanding and contracting the volume of a ceramic body according to a voltage frequency, generating periodic vibrations.

Such vibrations may be transferred to a board through external electrodes of the MLCC and solders connecting the external electrodes and the board, inducing the entirety of the board to act as an acoustically radiating surface emitting vibratory sound as noise.

Such vibratory sound may correspond to audio frequencies ranging from 20 Hz to 20,000 Hz, causing listener discomfort, and such vibratory sound, causing listener discomfort, is commonly known as acoustic noise.

Furthermore, as electronic devices used with mechanical components tend to have reduced noise generation, acoustic noise generated by an MLCC may be more often perceived by listeners.

When an operating environment of a device is significantly noise-free, a user may consider acoustic noise to be abnormal, recognizing it as a fault of the device. In addition, in a device having a voice communication function, acoustic noise overlapping audio output may degrade the performance of the device.

### SUMMARY

An aspect of the present disclosure provides a capacitor component in which acoustic noise is reduced when the capacitor component is mounted on a printed circuit board (PCB), or the like, and used.

Another aspect of the present disclosure provides a board having a capacitor component in which acoustic noise is reduced through having reduced vibrations.

According to an aspect of the present disclosure, a capacitor component includes: a capacitor including a plurality of internal electrodes, a capacitor body containing a piezoelectric material formed in a region between adjacent electrodes among the plurality of internal electrodes, and external electrodes connected to the plurality of internal electrodes; and support parts formed of a metal and disposed to be coupled to the capacitor and having an annular shape to alleviate vibrations generated by the capacitor.

The support parts may be disposed on a lower surface of the capacitor and connected to the external electrodes.

The support parts may be provided to correspond to the number of external electrodes.

The support parts may be disposed such that openings thereof are oriented in a lateral direction of the capacitor.

The support parts may be disposed such that openings thereof are oriented in a longitudinal direction of the capacitor.

A plurality of support parts may be provided, and openings provided in the plurality of support parts may be disposed to face each other.

The support parts may have a curved surface in at least a portion thereof.

The support parts may have a quasi-cylindrical shape and are configured to have an opening formed by removing a portion thereof in a thickness direction of the cylindrical structure.

Upper and lower surfaces of the quasi cylindrical structure may have an oval shape.

The support parts may further include a hole structure wherein a portion of the support part in a direction other than the thickness direction of the cylindrical structure is removed.

The hole structure may include the entirety of a portion of a side wall of the support part in the thickness direction of the cylindrical structure.

The hole structure may have a cross shape.

The hole structure may be formed in a curved region among regions forming side walls of the cylindrical structure.

The capacitor component may further comprise a conductive adhesive disposed between the capacitor and the support parts.

The capacitor component may further comprise an insulating layer disposed on a lower surface of the capacitor and coupled to the capacitor and the support parts.

The plurality of internal electrodes may be disposed to be perpendicular with respect to a mounting surface of the capacitor.

The plurality of internal electrodes may be disposed to be parallel with respect to a mounting surface of the capacitor.

The external electrodes may include first and second external electrodes, and the plurality of internal electrodes may include first and second internal electrodes respectively connected to the first and second external electrodes.

According to another aspect of the present disclosure, a board comprises a circuit board; a capacitor disposed on the circuit board and including a plurality of internal electrodes, a capacitor body containing a piezoelectric material formed in a region between adjacent electrodes among the plurality of internal electrodes, and external electrodes connected to the plurality of internal electrodes; and support parts disposed between the circuit board and the capacitor, formed of a metal, and disposed to be coupled to the capacitor and having an annular shape to alleviate vibrations generated by the capacitor.

The support parts may be disposed such that openings thereof are oriented in a lateral direction of the capacitor, and may have a curved surface in at least a portion thereof.

The board may further comprise a solder material bonding the circuit board and the support parts. The solder material may be limited in height in formation thereof by regions corresponding to the curved surfaces of the support parts.

According to another aspect of the present disclosure, a capacitor component comprises a capacitor including a plurality of internal electrodes, a capacitor body containing a piezoelectric material formed in a region between adjacent electrodes among the plurality of internal electrodes, and external electrodes connected to the plurality of internal electrodes; and support parts coupled to the capacitor and having a cylindrical shape. The support parts are hollow in an axial direction of the cylindrical shape and are oriented such that the axial direction of the cylindrical shape is parallel to a mounting surface of the capacitor where the support parts are coupled.

### BRIEF DESCRIPTION OF THE DRAWINGS

The above and other aspects, features and other advantages of the present disclosure will be more clearly understood from the following detailed description taken in conjunction with the accompanying drawings, in which:

FIGS. 1 and 2 are a perspective view and a cross-sectional view schematically illustrating a capacitor component according to an exemplary embodiment in the present disclosure;

FIG. 3 is a cross-sectional view illustrating a configuration in which support parts alleviate vibrations of a capacitor in the exemplary embodiment of FIGS. 1 and 2;

FIG. 4 is a cross-sectional view schematically illustrating a capacitor component according to a modified example of FIG. 2;

FIGS. 5 and 6 are cross-sectional views schematically illustrating capacitor components and boards having the same according to a modified example;

FIG. 7 is a perspective view schematically illustrating a capacitor component and a board having the same according to a modified example; and

FIGS. 8 through 11 are perspective views schematically illustrating various modified examples of a support part.

### DETAILED DESCRIPTION

Hereinafter, embodiments of the present inventive concept will be described as follows with reference to the attached drawings.

The present inventive concept may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “upper,” or “above” other elements would then be oriented “lower,” or “below” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present inventive concept will be described with reference to schematic views illustrating embodiments of the present inventive concept. In the drawings, for example, due to manufacturing techniques and/or tolerances, modifications of the shape shown may be estimated. Thus, embodiments of the present inventive concept should not be construed as being limited to the particular shapes of regions shown herein, for example, to include a change in shape results in manufacturing. The following embodiments may also be constituted by one or a combination thereof.

The contents of the present inventive concept described below may have a variety of configurations and propose only a required configuration herein, but are not limited thereto.

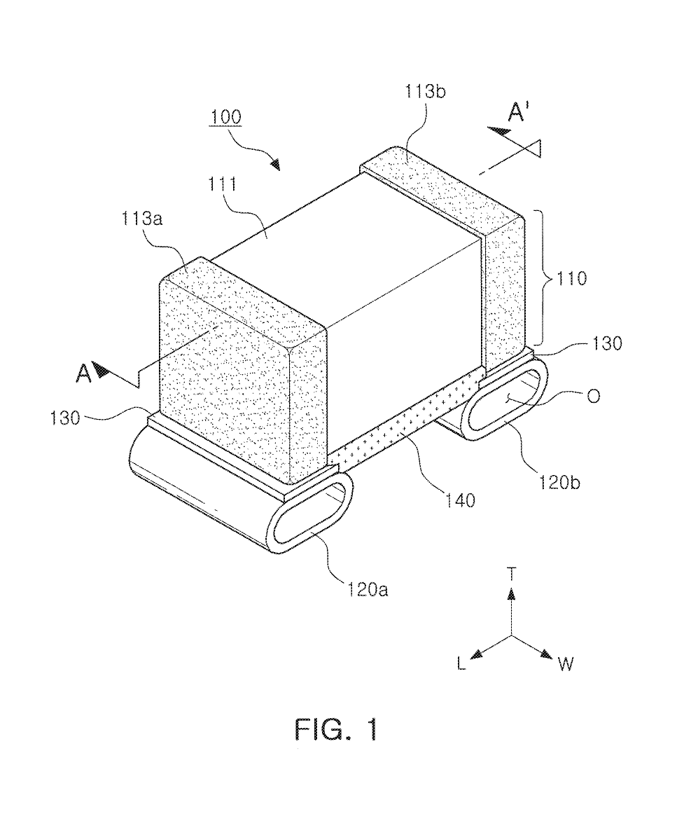

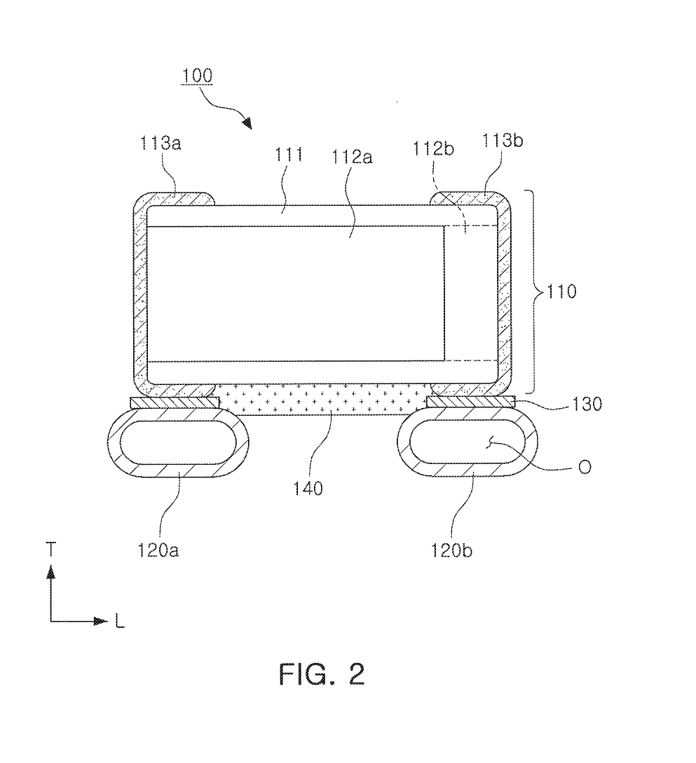

FIGS. 1 and 2 are a perspective view and a cross-sectional view schematically illustrating a capacitor component according to an exemplary embodiment in the present disclosure. Referring to FIGS. 1 and 2, a capacitor component 100 according to an exemplary embodiment includes a capacitor 110 and support parts 120a and 120b. Hereinafter, the components of the capacitor component 100 will be described in detail.

The capacitor 110 includes a plurality of internal electrodes 112a and 112b, a capacitor body 111 containing a piezoelectric material, and external electrodes 113a and 113b. The capacitor 110 may be employed in various forms, and for example, as illustrated in FIG. 2, the plurality of internal electrodes 112a and 112b may be disposed to be alternately connected to different external electrodes 113a and 113b. That is, it may be understood that the eternal electrodes include first and second external electrodes 113a and 113b and the first and second internal electrodes 112a and 112b are connected to the first and second external electrodes 113a and 113b, respectively. The capacitor body 111 may be formed in a region between respective electrodes among the plurality of internal electrodes 112a and 112b. For example, as illustrated in FIG. 2, the capacitor body 111 may accommodate the internal electrodes 112a and 112b therein. The capacitor body 111 may be formed of a dielectric material such as a ceramic material, or the like, known in the art, and such a ceramic material may be a piezoelectric material which may be changed in shape and volume when an electrical signal is applied thereto. As described above, the piezoelectric properties of the capacitor body 111 may cause unwanted acoustic noise, and in the present exemplary embodiment, such acoustic noise is reduced by utilizing the support parts 120a and 120b.

The dielectric material that may be included in the capacitor body 111 may include a high-k ceramic material, for example, a barium titanate (BaTiO₃)-based ceramic powder, or the like, but the material of the capacity body is not limited thereto. The BaTiO₃-based ceramic powder may include, for example, (Ba₁₋ₓCaₓ)TiO₃, Ba(Ti_{1-y}Ca_{y})O₃, (Ba₁₋ₓCaₓ)(Ti_{1-y}Zr_{y})O₃, or Ba(Ti_{1-y}Zr_{y})O₃ formed by partially employing calcium (Ca) or zirconium (Zr) in BaTiO₃, but the BaTiO₃-based ceramic powder is not limited thereto.

The support parts 120a and 120b may be disposed to be coupled to the capacitor 110 and serve as terminal parts when mounted on a circuit board, or the like. For example, as illustrated in FIGS. 1 and 2, the support parts 120a and 120b may be disposed below the capacitor 110 such that they may be connected to the external electrodes 113a and 113b of the capacitor 110. Here, the support parts 120a and 120b may be provided in an amount corresponding to the number of the external electrodes 113a and 113b.

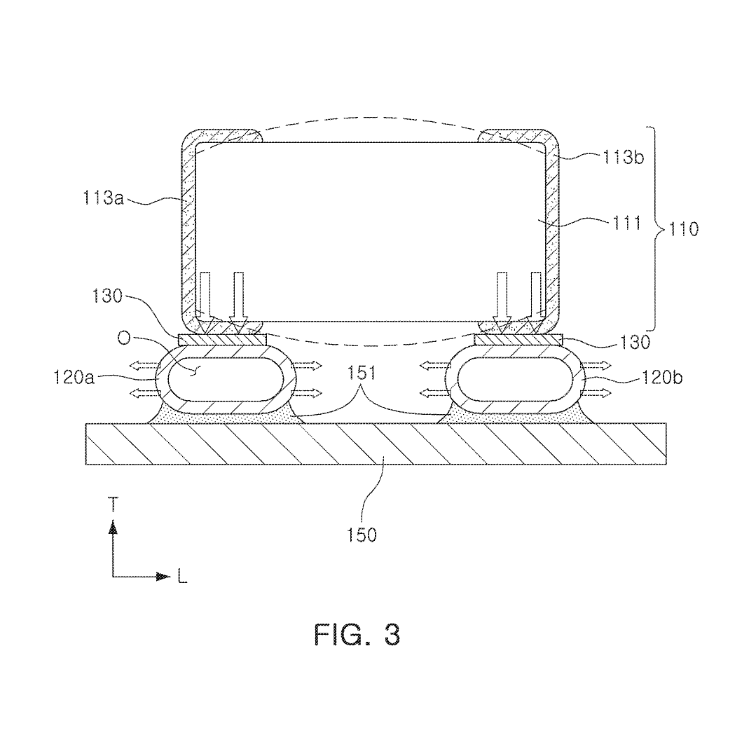

In addition to functioning as support structures and terminals, the support parts 120a and 120b are formed of a material and have an annular shape to reduce vibrations generated by the capacitor 110. Thus, noise generated by the capacitor 110 may be blocked or alleviated by the support parts 120a and 120b serving as buffers with respect to vibrations, reducing a negative influence on the board, or the like. In order for the support parts 120a and 120b to serve as terminal parts and buffers, the support parts 120a and 120b may be formed of a metal such as nickel, copper, or aluminum. A vibration reduction function of the support parts 120a and 120b will be described with reference to FIG. 3. FIG. 3 is a cross-sectional view illustrating a configuration in which the support parts 120a and 120b alleviate vibrations of the capacitor 110 in the exemplary embodiment of FIGS. 1 and 2, and here, in order to clarify the present disclosure, internal electrodes and an insulating layer are not illustrated. Instead, in order to illustrate the configuration in which the capacitor component is mounted, a circuit board 150 and a solder material 151 are illustrated, and the overall configuration in which the capacitor is mounted may be termed a capacitor component mounting board.

The support parts may have a cylindrical shape, and be hollow in an axial direction of the cylindrical shape. Furthermore, the support parts may be oriented such that the axial direction of the cylindrical shape is parallel to a mounting surface of the capacitor where the support parts are coupled.

Referring to FIG. 3, in the capacitor 110, in particular, the capacitor body 111 as a region containing a piezoelectric material may be changed in shape and volume as indicated by the dotted line when an electrical signal is applied thereto, and such a change is transmitted in the form of noise, such as vibrations, downwardly. The support parts 120a and 120b having an opening O formed therein distribute noise such as vibrations in a lateral direction, thus preventing noise from being transmitted to the board 150 or alleviating an amount of transmitted noise. To provide such a buffer function against noise, the support parts 120a and 120b may be disposed such that openings O thereof are oriented in a lateral direction of the capacitor 110, that is, in a direction parallel to the circuit board 150.

Also, in order to provide a more appropriate structure for effectively distributing vibrations in the lateral direction, the support parts 120a and 120b may have at least partially curved surfaces. In a specific exemplary embodiment, the support parts 120a and 120b may basically have a cylindrical structure. That is, as illustrated in FIG. 1, the support parts 120a and 120b may basically have a cylindrical structure and partial regions thereof are removed in a width direction to form the openings O. Here, preferably, the support parts 120a and 120b have an oval shape flat in upper and lower surfaces thereof, rather than a circular shape, so as to be appropriately coupled to the capacitor 110 and the circuit board. Thus, in the present disclosure, the cylindrical shape may include a quasi cylindrical structure, in particular, an oval structure flat in upper and lower surfaces thereof.

The vibration alleviation function of the support parts 120a and 120b featured through the curved shape is also related to the solder material 151. As illustrated in FIG. 3, the capacitor component is generally coupled to the circuit board 150 by the solder material 151, and here, the solder material 151 may be a medium transmitting vibrations generated by the capacitor component. Thus, as the amount of the solder material 151 in contact with the capacitor component increases, the potential for acoustic noise may also be increased. Thus, it is preferable to lower the height of the solder material 151 when formed within a range in which mechanical strength or electrical connectivity is not degraded, in order to alleviate vibrations. In this aspect, when the support parts 120a and 120b have an annular or curved shape as in the present exemplary embodiment, the solder material 151 may be limited in height in formation by the regions corresponding to the curved surfaces of the support parts 120a and 120b, and thus, acoustic noise may also be alleviated.

Referring to other components, the internal electrodes 112a and 112b described above are disposed in a vertically mounted manner with respect to the capacitor 110 and the support parts 120a and 120b. That is, the plurality of internal electrodes 112a and 112b may be disposed to be perpendicular with respect to a direction in which the capacitor 110 and the support parts 120a and 120b are arranged. The vertical mounting scheme may be appropriate for a reduction in equivalent series resistance (ESR) or equivalent serial inductance (ESL) by reducing a current path, or the like, and in addition, since vibrations are alleviated in the thickness direction of the capacitor 110 illustrated in FIG. 3, generation of acoustic noise may also be alleviated. This is because the internal electrodes 112a and 112b disposed in the vertically mounted manner may generate a larger amount of vibrations in the direction perpendicular to the capacitor 110 than in the thickness direction of the capacitor 110.

The capacitor component 100 may further include a conductive adhesive 130 between the capacitor 110 and the support parts 120a and 120b in order to mechanically or electrically bond them, and any material may be used as long as it can realize such a bonding function. For example, a conductive epoxy or eutectic metals may be used as the conductive adhesive 130. However, the conductive adhesive 130 may not be essential in the present exemplary embodiment and the capacitor 110 and the support parts 120a and 120b may be directly bonded.

An insulating layer 140 may be provided on a lower surface of the capacitor 110 and coupled to the capacitor 110 and the support parts 120a and 120b. The insulating layer 140 may serve to fasten the capacitor 110 and the support parts 120a and 120b therebelow, thus enhancing bonding strength between the capacitor 110 and the support parts 120a and 120b.

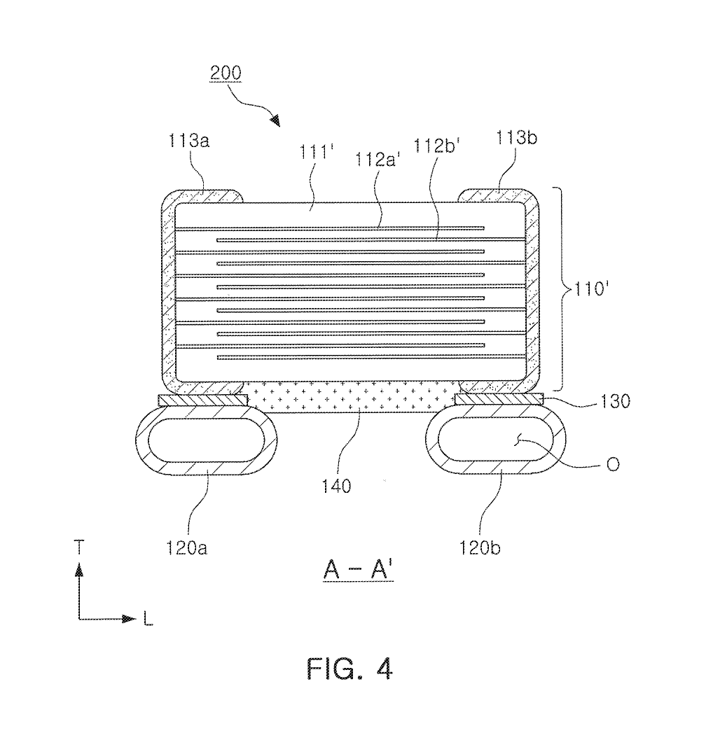

FIG. 4 is a cross-sectional view schematically illustrating a capacitor component according to a modified example of FIG. 2. The capacitor according to the exemplary embodiment of FIG. 4 is different from that of the previous exemplary embodiment in shape. In detail, compared with the capacitor component 100 according to the exemplary embodiment of FIGS. 1 and 2, a capacitor component 200 according to the exemplary embodiment of FIG. 4 may be different in disposition of internal electrodes 112a′ and 112b′. That is, unlike the plurality of internal electrodes 112a and 112b disposed to be perpendicular with respect to a direction in which the capacitor 110 and the support parts 120a and 120b are arranged (that is, a vertical direction in relation to FIG. 4), the plurality of internal electrodes 112a′ and 112b′ according to the exemplary embodiment of FIG. 4 may be disposed to be parallel with respect to the direction in which the capacitor 110 and the support parts 120a and 120b are arranged.

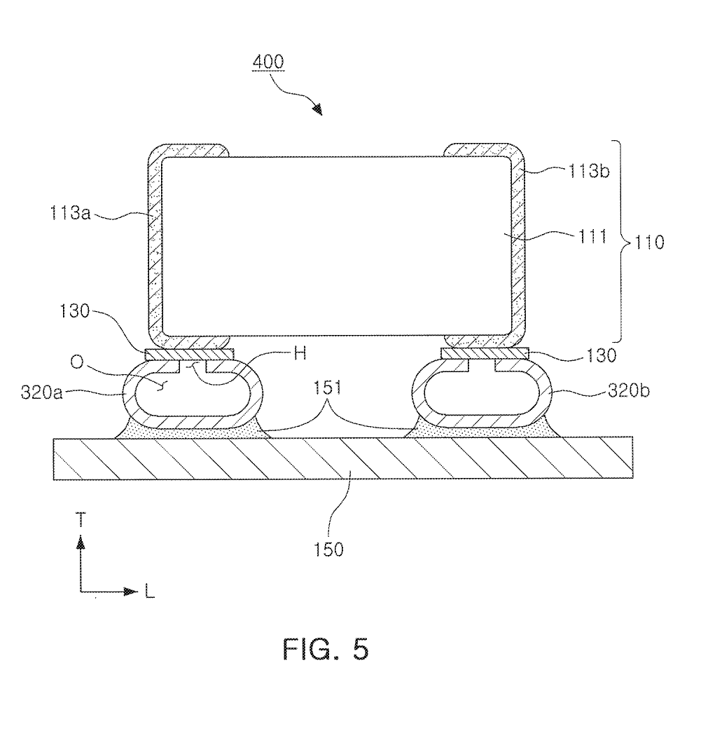

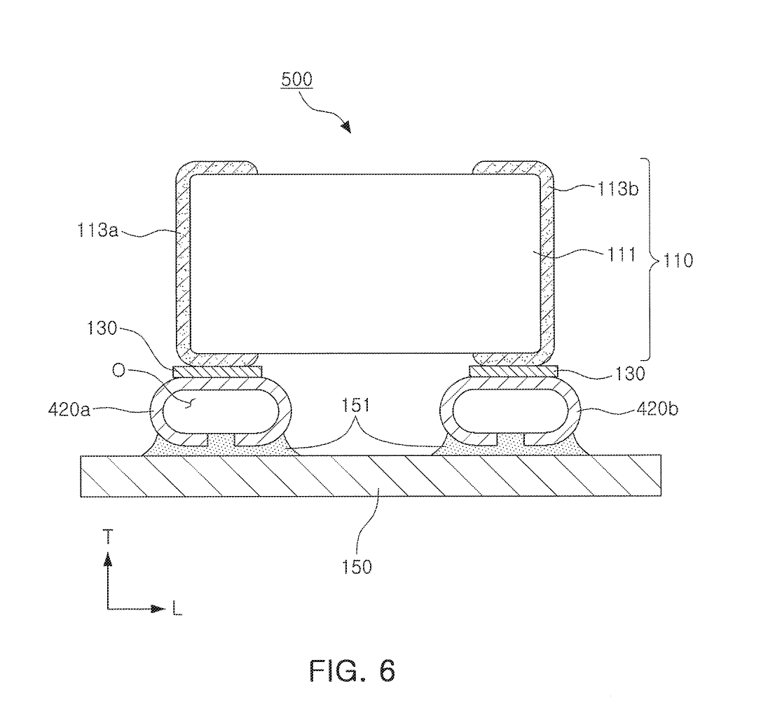

Hereinafter, capacitor components and boards having the same according to various modified examples will be described. FIGS. 5 and 6 are cross-sectional views schematically illustrating capacitor components and boards having the same according to a modified example. In this exemplary embodiment, a capacitor component 400 includes a capacitor body 110 and support parts 320a and 320b, the same as those of the capacitor component 100 of the previous exemplary embodiment, except for only a shape of the support parts 320a and 320b. This will be described. In the present exemplary embodiment, the support parts 320a and 320b have an additional hole structure H in addition to the openings O. The hole structures H are formed by removing portions of the support parts 320a and 320b in a direction other than the thickness direction of the cylindrical shape or a quasi cylindrical shape, and the support parts 320a and 320b may have at least one hole structure H. The hole structure H may prevent the solder material 151 from being increased in height caused as the solder material 151 accumulates, and contribute to enhancement of bonding strength between the capacitor 110 and the circuit board 150. The hole structure H may be oriented in a direction in which the capacitor 110 is disposed as in the exemplary embodiment of FIG. 5, or conversely, the hall structure H may be oriented in a direction toward the circuit board 150 like support parts 420a and 420b provided in a capacitor component 500 of FIG. 6.

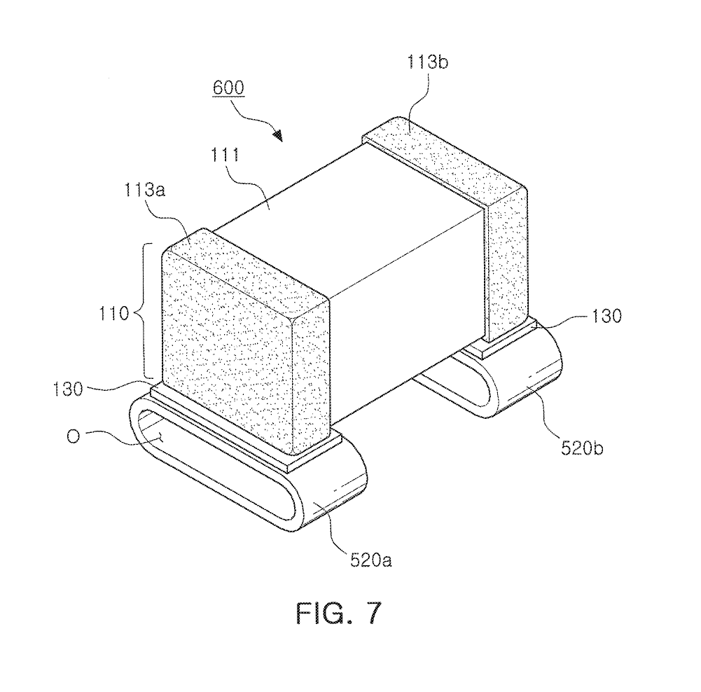

Also, even though the support parts proposed in the present disclosure have the same shape, they may be coupled to the capacitor in different manners. FIG. 7 is a perspective view schematically illustrating a capacitor component and a board having the same according to a modified example. In the present exemplary embodiment, a capacitor component 600 may have a capacitor 110, support parts 520a and 520b, the same as those of the capacitor component 100 of the previous exemplary embodiment, except for an arrangement of the support parts 520a and 520b. As illustrated in FIG. 7, a plurality of support parts 520a and 520b have a configuration resulting from rotating the support parts 120a and 120b by 90°. That is, the plurality of support parts 520a and 520b may be disposed such that the openings O thereof face each other.

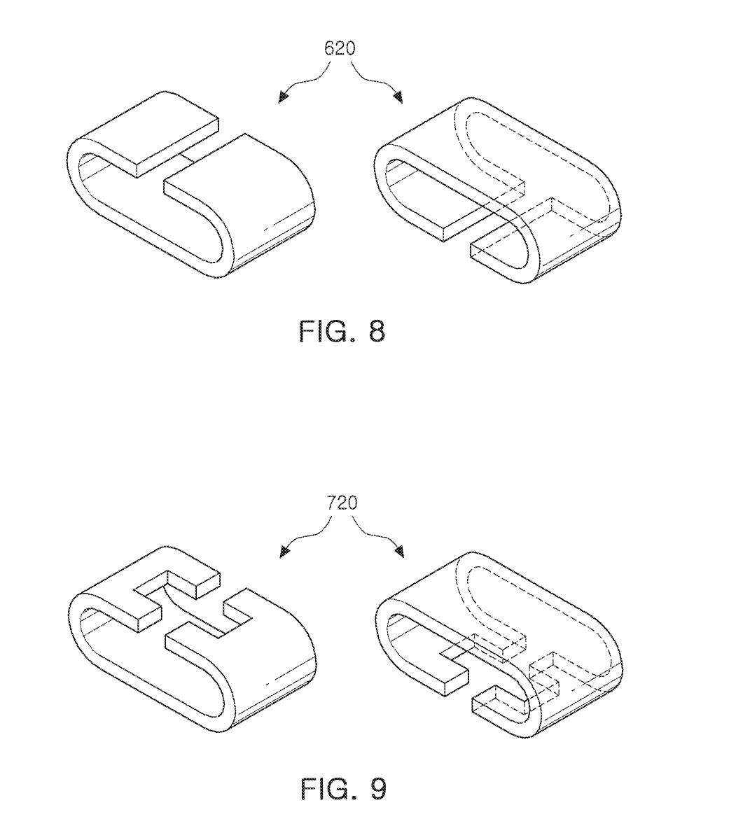

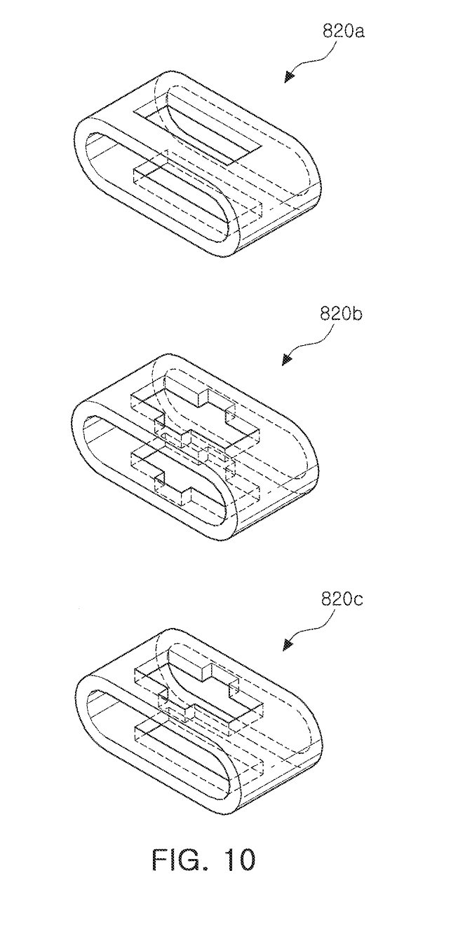

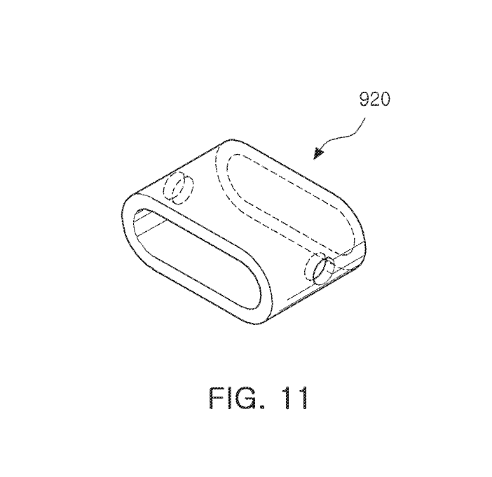

FIGS. 8 through 11 are perspective views schematically illustrating various modified examples of a support part, in which a shape of the support part, specifically, the hole structure thereof, is variously modified in consideration of the functions of the support parts, that is, the vibration alleviation function, the terminal function, and the bonding strength enhancement function. First, as in the example illustrated in FIG. 8, support parts 620 may have a structure in which portions of regions forming side walls of the basic cylindrical or quasi cylindrical structure are entirely removed in a thickness direction. Also, as in the example illustrated in FIG. 9, support parts 720 may have a structure in which portions of regions forming side walls of the basic cylindrical or quasi cylindrical structure are entirely removed in a height direction of the cylindrical or quasi cylindrical structure and other regions are removed in a direction perpendicular thereto, resulting in a hole structure having a cross shape similar to a “+”. Also, as in the example illustrated in FIG. 10, support parts 820a, 820b, and 820c may have hole structures formed by removing two regions forming side walls of the basic cylindrical structure to have a shape similar to “1” or “+”, and here, the two hole structures of the single support part 820c may have different shapes. Also, as in the example illustrated in FIG. 11, a support part 920 may have hole structures formed in curved regions among regions forming side walls of the basic cylindrical or quasi cylindrical structure, and the hole structures formed in the curved regions such as in the present exemplary embodiment may further contribute to alleviating vibrations and stress generated by the capacitor by distributing the vibrations and stress.

As set forth above, according to exemplary embodiments of the present disclosure, acoustic noise of the capacitor component may be alleviated by using the support parts able to reduce or prevent vibrations generated by the capacitor. In addition, employing such a capacitor component, a board having excellent vibration performance may be provided.

While exemplary embodiments have been shown and described above, it will be apparent to those skilled in the art that modifications and variations could be made without departing from the scope of the present invention as defined by the appended claims.

What is claimed is:

1. A capacitor component comprising:
a capacitor including a plurality of internal electrodes, a capacitor body containing a piezoelectric material formed in a region between adjacent electrodes among the plurality of internal electrodes, and external electrodes connected to the plurality of internal electrodes; and
support parts formed of a metal and disposed to be coupled to the capacitor and having an annular shape to alleviate vibrations generated by the capacitor.

2. The capacitor component of claim 1, wherein the support parts are disposed on a lower surface of the capacitor and connected to the external electrodes.

3. The capacitor component of claim 2, wherein the support parts are provided to correspond to the number of external electrodes.

4. The capacitor component of claim 1, wherein the support parts are disposed such that openings thereof are oriented in a lateral direction of the capacitor.

5. The capacitor component of claim 1, wherein the support parts are disposed such that openings thereof are oriented in a longitudinal direction of the capacitor.

6. The capacitor component of claim 1, wherein a plurality of support parts are provided, and openings provided in the plurality of support parts are disposed to face each other.

7. The capacitor component of claim 1, wherein the support parts have a curved surface in at least a portion thereof.

8. The capacitor component of claim 7, wherein the support parts have a quasi-cylindrical shape and are configured to have an opening formed by removing a portion thereof in a thickness direction of the cylindrical structure.

9. The capacitor component of claim 8, wherein upper and lower surfaces of the quasi cylindrical structure have an oval shape.

10. The capacitor component of claim 8, wherein the support parts further include a hole structure wherein a portion of the support part in a direction other than the thickness direction of the cylindrical structure is removed.

11. The capacitor component of claim 10, wherein the hole structure includes the entirety of a portion of a side wall of the support part in the thickness direction of the cylindrical structure.

12. The capacitor component of claim 10, wherein the hole structure has a cross shape.

13. The capacitor component of claim 10, wherein the hole structure is formed in a curved region among regions forming side walls of the cylindrical structure.

14. The capacitor component of claim 1, further comprising a conductive adhesive disposed between the capacitor and the support parts.

15. The capacitor component of claim 1, further comprising an insulating layer disposed on a lower surface of the capacitor and coupled to the capacitor and the support parts.

16. The capacitor component of claim 1, wherein the plurality of internal electrodes are disposed to be perpendicular with respect to a mounting surface of the capacitor.

17. The capacitor component of claim 1, wherein the plurality of internal electrodes are disposed to be parallel with respect to a mounting surface of the capacitor.

18. The capacitor component of claim 1, wherein the external electrodes include first and second external electrodes, and the plurality of internal electrodes include first and second internal electrodes respectively connected to the first and second external electrodes.

19. A board comprising:
a circuit board;
a capacitor disposed on the circuit board and including a plurality of internal electrodes, a capacitor body containing a piezoelectric material formed in a region between adjacent electrodes among the plurality of internal electrodes, and external electrodes connected to the plurality of internal electrodes; and
support parts disposed between the circuit board and the capacitor, formed of a metal, and disposed to be coupled to the capacitor and having an annular shape to alleviate vibrations generated by the capacitor.

20. The board of claim 19, wherein the support parts are disposed such that openings thereof are oriented in a lateral direction of the capacitor, and have a curved surface in at least a portion thereof.

21. The board of claim 20, further comprising a solder material bonding the circuit board and the support parts, wherein the solder material is limited in height in formation thereof by regions corresponding to the curved surfaces of the support parts.

22. A capacitor component comprising:
a capacitor including a plurality of internal electrodes, a capacitor body containing a piezoelectric material formed in a region between adjacent electrodes among the plurality of internal electrodes, and external electrodes connected to the plurality of internal electrodes; and
support parts coupled to the capacitor and having a cylindrical shape,
wherein the support parts are hollow in an axial direction of the cylindrical shape and are oriented such that the axial direction of the cylindrical shape is parallel to a mounting surface of the capacitor where the support parts are coupled.

23. The capacitor component of claim 22, wherein the support parts are made of a metal.

24. The capacitor component of claim 22, further comprising a conductive adhesive disposed between the external electrodes and the support parts and an insulating layer disposed on a lower surface of the capacitor and coupled to the capacitor and the support parts.
